(19) United States
(12) Patent Application Publication
(10) Pub. No.: US 2024/0370632 A1
(43) Pub. Date: Nov. 7, 2024

(54) METHOD FOR PERFORMING DESIGN RULE CHECKS

(71) Applicant: GLOBALFOUNDRIES U.S. Inc., Malta, NY (US)

(72) Inventors: Romain FEUILLETTE, Willistion, VT (US); Nolan Pavek, Austin, TX (US); Navneet Jain, Milpitas, CA (US); Adam Zeeb, Midland, MI (US); Bowen Zhal, Coral Gables, FL (US)

(21) Appl. No.: 18/312,514

(22) Filed: May 4, 2023

(51) Int. Cl. G06F 30/398

(52) U.S. Cl. CPC G06F 30/398

(57) ABSTRACT

A process for performing a design rule check (DRC) by a computer may comprise receiving a DRC result comprising a plurality of DRC errors, the DRC result corresponding to a DRC deck comprising a plurality of rules and a design layout database comprising a plurality of components; classifying, using a neural network, each of the plurality of DRC errors according to whether that DRC should be ignored; and producing a final report including a plurality of respective indications of whether the plurality of DRC errors should be ignored. Performing the process may further include the receiving mistake feedback regarding the final report; updating, using the mistake feedback, a DRC result dataset comprising a plurality of dataset entries; and re-training the neural network using the updated DRC result dataset.

### FIELD OF THE DISCLOSURE

The present disclosure relates to performing a design rule check (DRC) on a design for an electronic device, and in particular to determining whether a DRC error corresponds to an actual error in the design that needs to be addressed.

### BACKGROUND

Design rules ensure that a design of an electronic device, such as an integrated circuit, will produce a device with acceptable performance, reliability, manufacturing yield, or combinations thereof. Design rules specify, for example, constraints on width, spacing, areas, aspect ratios, fill density, and the like for elements of integrated circuit, and are usually specific to the process that will be used to manufacture the integrated circuit.

A set of design rules for a process may be referred to as a DRC deck. Performing a design rule check (DRC) comprises evaluating a design to see if it conforms with the design rules in the DRC deck for the process on which the design is to be manufactured. The DRC may be performed by applying the DRC deck to a design database (e.g., a design layout database) including the layout of the electronic device or to a portion (e.g., a block) of the electronic device in the design database.

A DRC result may correspond to a list having entries (i.e., DRC errors) indicating a design rule that was violated, a component of the design that produced the violation, and a number of times that design rule was violated within that component.

The DRC result may include a large number of such entries; however, especially in early stages of the design process, many of those DRC errors may be ignored. Also, in some situations, some DRC errors may be waived.

The process (known as annotating the DRC errors) of determining which DRC errors to ignore or waive, and which should be addressed by altering the design of the electronic device can be overwhelming, which may result in design time and expenditures increasing and in some important DRC errors being overlooked.

### SUMMARY

Embodiments of the present disclosure relate to performing a Design Rule Check (DRC), and in particular to determining annotations for DRC errors in a DRC result using a neural network and the design database, wherein the annotations indicate whether the corresponding DRC error should be ignored.

In an embodiment, a method of performing a design rule check (DRC) performed by a computer comprises receiving a DRC result comprising a plurality of DRC errors, the DRC result corresponding to a DRC deck comprising a plurality of rules and a design layout database comprising a plurality of components; classifying, using a neural network, each of the plurality of DRC errors according to whether that DRC error should be ignored; and producing a final report including a plurality of respective indications of whether the plurality of DRC errors should be ignored. Each DRC error comprises an indication of a rule of the plurality of rules, an indication of a component of the plurality of components, and a count of the number of times the rule was violated by the component.

In another embodiment, a system for performing a DRC comprises a processor and a neural network. The system is configured to perform steps comprising receiving a DRC result comprising a plurality of DRC errors, the DRC result corresponding to a DRC deck comprising a plurality of rules and a design layout database comprising a plurality of components; classifying, using a neural network, each of the plurality of DRC errors according to whether that DRC error should be ignored; and producing a final report including a plurality of respective indications of whether the plurality of DRC errors should be ignored. Each DRC error comprises an indication of a rule of the plurality of rules, an indication of a component of the plurality of components, and a count of the number of times the rule was violated by the component.

In another embodiment, a non-transient computer-readable medium (CRM) comprises computer programming instructions that, when executed by a processor, perform a method comprising receiving a DRC result comprising a plurality of DRC errors, the DRC result corresponding to a DRC deck comprising a plurality of rules and a design layout database comprising a plurality of components; classifying, using a neural network, each of the plurality of DRC errors according to whether that DRC error should be ignored; and producing a final report including a plurality of respective indications of whether the plurality of DRC errors should be ignored. Each DRC error comprises an indication of a rule of the plurality of rules, an indication of a component of the plurality of components, and a count of the number of times the rule was violated by the component.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 illustrates a design rule check (DRC) process according to an embodiment.

FIG. 2A illustrates a DRC Result Classification process according to an embodiment.

FIG. 2B illustrates a DRC Result Classification Update process according to an embodiment.

FIGS. 3A and 3B illustrate preprocessor encodings according to an embodiment.

FIGS. 4A illustrates a DRC result according to an embodiment.

FIG. 4B illustrates a pre-processed DRC result according to an embodiment.

FIG. 4C illustrates entries in a Final Report according to an embodiment.

FIG. 4D illustrates entries in a DRC Result Dataset according to an embodiment.

FIG. 5 illustrates a simplified representation of a neural network according to an embodiment.

FIG. 6 illustrates an apparatus for performing a design rule check (DRC) process according to an embodiment.

### DETAILED DESCRIPTION

Exemplary embodiments of the present disclosure will be described below in more detail with reference to the accompanying drawings. The inventive features may, however, be embodied in different forms and should not be construed as limited to the embodiments set forth herein. Rather, these embodiments are provided so that this disclosure will be thorough and complete, and will fully convey the scope of the present claims to those skilled in the art. Throughout the disclosure, like reference numerals refer to like parts throughout the various figures and embodiments.

It will be understood that, although the terms “first” and/or “second” may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

The drawings are not necessarily to scale and in some instances, proportions may have been exaggerated in order to clearly illustrate features of the embodiments.

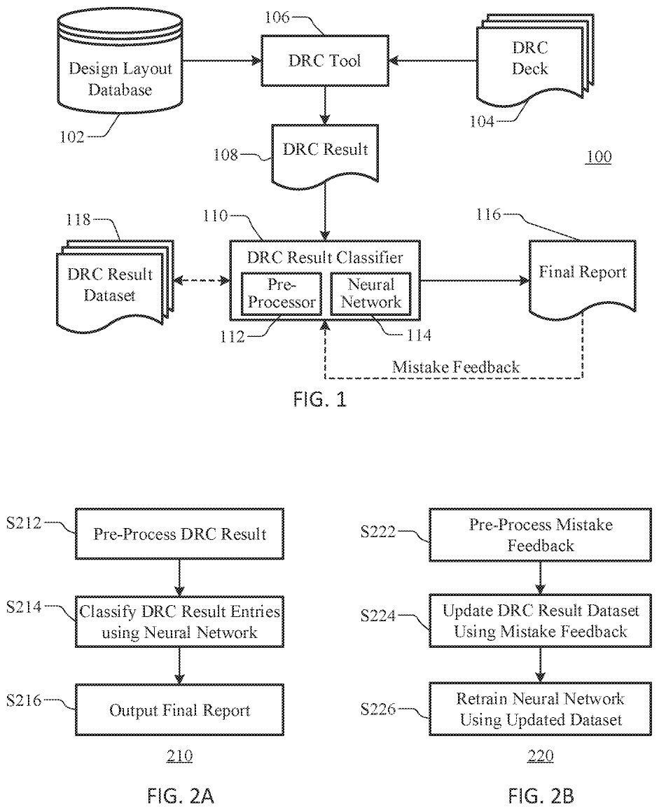

FIG. 1 illustrates a DRC process 100 according to an embodiment.

The DRC process 100 uses a DRC tool 106 to apply a DRC Deck 104 comprising a plurality of design rules to a Design Layout Database 102, and produces a DRC Result 108 indicating one or more DRC errors. A DRC error may indicate which design rule was violated, which object in the Design Layout Database 102 violated that rule, and how many times that object violated that rule. A DRC error may also indicate a stack name indicating a layer of the design (for example, “metal2”), a text description of the rule, or both. An illustrative example of a DRC Result 108 produced by the DRC Tool 106 is provided in FIG. 4A, which will be described below.

A DRC Result Classifier 110 processes the DRC Result 108 to determine which DRC errors represent issues that may be ignored or waived, as opposed to issues that should be corrected. A DRC error may be ignored or waived when, for example, the object that violated the rule is a test structure, when the design is an intermediate (incomplete) design and the DRC error is likely to be remedied in the course of finalizing design, or when the DRC Deck needs to be updated.

The DRC Result Classifier 110 includes a Preprocessor 112 and a Neural Network 114. The Preprocessor 112 transforms the DRC Result 108 into an encoded form that is more suitable for use as an input to the Neural Network 114. The Neural Network 114 determines whether the DRC errors in the DRC Result 108 should be ignored or not.

Using the Preprocessor 112 and the Neural Network 114, the DRC Result Classifier 110 produces a Final Report 116 that may include all the DRC errors and an indication for each DRC error of whether that DRC error should be ignored. In an embodiment, the DRC Result Classifier 110 may be configurable to output a Final Report 116 including only the DRC errors that should not be ignored.

The Final Report 116 may be reviewed (for example, by one or more designers, some other automated process, or both) and any mistakes identified in the Final Report 116 (such as a DRC error being indicated as ignorable when it should not be, or a DRC error not being indicated as ignorable when it should be) provided to the DRC Result Classifier 110 as Mistake Feedback.

In response to receiving the Mistake Feedback, the DRC Result Classifier 110 may update the DRC Result Dataset 118 that was used to train the Neural Network 114, and may retrain the Neural Network 114 using the updated DRC Result Dataset 118. The retrained Neural Network 114 would be used in subsequent performance of the DRC process 100.

In an embodiment, when the DRC Deck 104 is provided to a user of the DRC process 100 (such as, for example, when a foundry supplies a DRC deck for a process to a client intending to use that process), an initial DRC Result Dataset 118 corresponding to the provided DRC Deck 104, a Neural Network 114 trained according to such an initial DRC Result Dataset 118, or both may also be provided to the user.

Subsequently, the user of the DRC process 100 may update the provided DRC Result Dataset 118 to create a DRC Result Dataset 118 specific to that user, and may retrain the Neural Network 114 to produce a Neural Network 114 specific to that user.

Different DRC Result Datasets 118 may be used for different stages of a design process for a device, respectively, so that respective different Neural Networks 114 may be used in the DRC Result Classifier 110 for the different stages.

FIG. 2A illustrates a DRC Result Classification process 210 (hereinafter, Classification process 210) according to an embodiment. The Classification process 210 may be performed by the DRC Result Classifier 110 of FIG. 1. The Classification process 210 is performed when a DRC Result such as the DRC Result 108 of FIG. 1 is received.

At S212, the Classification process 210 pre-processes the DRC Result. The pre-processing transforms the text-based DRC Result into a form more amenable to use by a neural network by encoding text fields in the DRC Result into numerical values.

The encoding of the text fields into numerical values may be performed using, for example, preprocessing functionality provided by scikit-learn (referred to herein as sklearn). In an embodiment, an encoder such as the sklearn LabelEncoder may be used to transforms each unique value in the text field(s) to a corresponding unique integer within a numerical range. In another embodiment, an encoder such as sklearn count vectorization that encodes each unique value in the text field(s) to a corresponding unique Boolean vector may be used to create the encodings, which may allow additional unique values to be added to the encodings later without changing the previous encodings.

In another embodiment, character-based text tokenization may be used to create the encodings for the text values in the DRC Result, which may improve the neural network's ability to take into account similarity between two text values (such as between “Design Rule #1” and “Design Rule #1bis”) and to enable the handling of rules not present in the database that was used to train the neural network. In an embodiment, the character-based text tokenization may produce an encoding for rules, components, or both based on both the name of the rule or component and a description thereof.

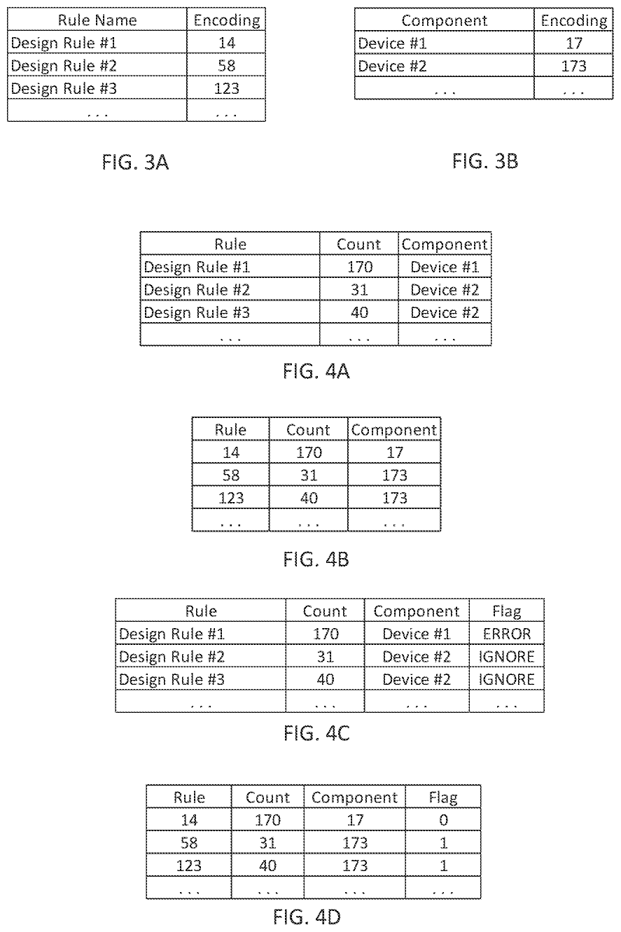

FIGS. 3A and 3B illustrate preprocessor encodings according to an embodiment. FIG. 3A illustrates encoding of DRC rule names, wherein the rule with the name “Design Rule #1” is encoded as 14, the rule with the name “Design Rule #2” is encoded as 58, and so on. FIG. 3B illustrates encoding of component names, wherein the component with the name “Device #1” is encoded as 17, the component with the name “Device #2” is encoded as 173, and so on.

FIGS. 4A illustrates an illustrative DRC Result according to an embodiment, and FIG. 4B illustrates a corresponding pre-processed DRC Result according to an embodiment. Each entry in the DRC result and in the pre-processed DRC Result includes an indication of a rule of a DRC Deck, an indication of a component of a design layout database, and a count of the number of times the rule was violated by the component.

The pre-processed DRC Result of FIG. 4B may be produced from the DRC Result of FIG. 4A by pre-processing using the encodings shown in FIGS. 3A and 3B so that, for example, the DRC error {“Design Rule #1” 170, “Device #1”} is encoded as {14, 170, 17}, and so on.

Returning to FIG. 2A, at S214 the Classification process 210 classifies the pre-processed DRC errors using the Neural Network 114. The encoded rule name, count, and encoded component name are provided to the Neural Network 114, and the Neural Network 114 produces an indication of whether the DRC error can be ignored.

In embodiments, the indication of whether the DRC error can be ignored may be a Boolean value indicating either true or false. In another embodiment, the indication of whether the DRC error can be ignored may be a confidence value ranging from 0 to 1.

At S216, the Classification process 210 produces the Final Report 116 by associating results from the Neural Network 114 with the corresponding DRC errors and unencoding the values in the DRC errors to produce entries respectively corresponding to the DRC errors in the Final Report 116. In embodiments, additional information (such as corresponding rule descriptions and component restrictions) may be added to the entries in the Final Report 116. The Final Report 116 may then be provided to a designer or to another tool used in the design process.

FIG. 4C illustrates entries in a Final Report 116 produced by the Classification process 210 according to an embodiment.

The Final Report 116 includes an entry for each DRC Error in the DRC Result 108, the entry including the Rule, Count, and Component information for the DRC Error and the result from the classification of the DRC Error by the Neural Network 114.

In the illustrated embodiment, the result of the classification of the DRC error by the Neural Network 114 indicates whether the error is an error that should be addressed or is an error that should be ignored. In another embodiment, the result of the classification of the DRC error by the Neural Network 114 is a confidence that the error should be ignored (such as may be expressed as a value between 0 to 1, which 0 indicating a high confidence that the DRC error is an actual error and 1 indicating a high confidence that the DRC Error should be ignored).

In the illustrated embodiment, all DRC errors in the DRC Result 108 have a corresponding entry in the Final Report 116. In another embodiment, DRC errors that are not classified as being ignorable (or, in an embodiment producing a confidence value, not classified as being ignorable with a confidence value above a threshold value) have corresponding entries in the Final Report 116, and DRC errors that are classified as being ignorable (or classified as being ignorable with a confidence value above a threshold value) do not have corresponding entries in the Final Report 116.

FIG. 2B illustrates a DRC Result Classification Update process 220 (hereinafter, Update process 220) according to an embodiment. The Update process 220 may be performed by the DRC Result Classifier 110 of FIG. 1. The Update process 220 is performed when Mistake Feedback regarding a Final Report 116 is provided to the DRC Result Classifier 110.

The Final Report 116 may include an identifier indicating the Neural Network 114 that produced the Final Report 116, the DRC Result Dataset 118 used to train that Neural Network 114, or both, and the Mistake Feedback may include one or more of those indications. In another embodiment, the Final Report 116 may include a unique identifier for itself, and the DRC Result Classifier 110 may maintain a database of which Neural Network 114 produced the Final Report 116 having that unique identifier, the Result Dataset 118 used to train that Neural Network 114, or both. Accordingly, in an environment having multiple distinct Neural Network 114 intended for classification of DRC errors in different contexts, the Update process may identify the Neural Network 114 and DRC Result Dataset 118 to update based on an identifier in the Mistake Feedback.

The Mistake Feedback may include an entry from the Final Report 116 and an indication that the entry was erroneous (e.g., that it was marked “Ignore” when it should not have been, or vice-versa) or an indication of what the result of the classification process should have been. In an embodiment where some DRC errors do not have corresponding entries in the Final Report 116, the Mistake Feedback may include a DRC error and an indication that it should have been included in the Final Report. Entries in the Mistake Feedback may have a format similar to that of entries in the Final Report, such as is shown in FIG. 4C, discussed above, but embodiments are not limited thereto.

At S222, in the illustrated embodiment wherein the DRC Result Dataset 118 includes entries with encoded text values, as described above, the Update process 220 may pre-process the Mistake Feedback in the same manner as described with respect to S212 of Classification process 210 of FIG. 2A. In another embodiment wherein text values in entries in the DRC Result Dataset 118 are preserved as text values, S222 may be skipped.

At S224, the Update process 220 updates the DRC Result Dataset 118 used to train the Neural Network 114 that produced the Final Report 116 using the (in some embodiments, pre-processed) Mistake Feedback that relates to that Final Report 116.

Incorporating the Mistake Feedback may include replacing a previous entry in the DRC Result Dataset 118 that the Mistake Feedback indicates is erroneous, adding a new entry to the DRC Result Dataset 118 when an entry in the Mistake Feedback has no corresponding entry in the DRC Result Dataset 118, or both.

For example, when the DRC Result Dataset 118 includes a dataset entry corresponding to a mistake entry in the Mistake Feedback, the flag or value related to whether DRC errors corresponding to that dataset entry may be ignored may be updated with the corresponding value from the mistake entry.

In embodiments, a dataset entry corresponds to a mistake entry when the Rule, Count, and Component in the dataset entry all match the corresponding fields in the mistake entry. In another embodiment, a dataset entry corresponds to a mistake entry when the Rule and Component in the dataset entry both match the corresponding fields in the mistake entry and the Count is similar (for example, within a pre-determined percentage) of the Count in the Mistake entry.

In embodiments, when no dataset entry in the DRC Result Dataset 118 corresponds to a mistake entry, a new data set entry corresponding to the mistake entry (for example, having the same Rule, Count, Component, and value related to ignorability) may be added to the DRC Result Dataset 118.

In other embodiments, whether a corresponding dataset entry exists is not determined, and the DRC Result Dataset 118 is updated by adding new dataset entries corresponding to the mistake entries.

FIG. 4D illustrates a DRC Result Dataset 118 according to an embodiment. In the embodiment shown in FIG. 4D, the dataset entries include text values (such as Rule and Component names) encoded as integers, in accordance with the encoding discussed with respect to S222 of FIG. 2B, but embodiments are not limited thereto. For example, in other embodiments, the text values are stored as text.

The dataset entries shown in FIG. 4D each include an integer corresponding to a name of a rule, a count, an integer corresponding to a name of a component, and a flag having a value of 1 if the dataset entry corresponds to a DRC error that should be ignored and a value of 1 otherwise.

At S226, the Neural Network 114 is retrained using the updated DRC Result Dataset 118. The updated DRC Result Dataset 118 may include tens of thousands of dataset entries or more; for example, a typical DRC Result Dataset 118 may include over one million dataset entries. As processes for retraining a neural network are widely known in the art, the details thereof are omitted for brevity. The retrained Neural Network 114 may then the used in subsequent performances of the Classification process 210.

FIG. 5 illustrates a simplified representation of a neural network 500. The neural network 500 is provided to explain the Neural Network 114 according to an embodiment, but has far fewer nodes and synapses than a practical Neural Network 114 capable of performing useful classification of DRC errors. In an embodiment, the neural network 500 is a Convolutional Neural Network (CNN), but embodiments are not limited thereto.

The neural network 500 comprises an input layer, a first layer (layer 1), a second layer (layer 2), a third layer (layer 3), and an output layer. The layers are connected using a plurality of synapses, shown as lines in FIG. 5.

The input layer includes first, second, and third input nodes 502A, 502B, and 502C, which respectively receive a Rule identifier, a Count, and a Component identifier corresponding to a DRC error.

Each node in the input layer is connected by a unique synapse to every layer 1 nodes 504 in layer 1. Although FIG. 5 shows only 20 layer 1 nodes 504, a practical embodiment of Neural Network 114 would include over 100 (for example, 256) layer 1 nodes 504. Accordingly, several hundred synapses, each having a corresponding weight determined by training the neural network 500, would be used to connect the input nodes 502A, 502B, and 502C to the layer 1 nodes 504, and hundreds of mathematical operations (typically matrix multiplications) collectively using several hundred or more input values would be performed in layer 1.

Each layer 1 node 504 in layer 1 is connected by a unique synapse to every layer 2 node 506 in layer 2. Although FIG. 5 shows only 20 layer 2 nodes 506, a practical embodiment of Neural Network 114 would include over 100 (for example, 256) layer 2 nodes 506. Accordingly, tens of thousands of synapses or more, each having a corresponding weight determined by training the neural network 500, would be used to connect the layer 1 nodes 504 to the layer 2 nodes 506, and hundreds of mathematical operations (typically including matrix multiplications) collectively using tens of thousands of input values would be performed in layer 2.

Each layer 2 node 506 in layer 2 is connected by a unique synapse to every layer 3 node 508 in layer 3. Although FIG. 5 shows only 20 layer 3 nodes 508, a practical embodiment of Neural Network 114 would include over 100 (for example, 256) layer 3 nodes 508. Accordingly, tens of thousands of synapses or more, each having a corresponding weight determined by training the neural network 500, would be used to connect the layer 2 nodes 506 to the layer 3 nodes 508, and hundreds of mathematical operations (typically matrix multiplications) collectively using tens of thousands of input values would be performed in layer 3.

Each layer 3 node 508 in layer 3 is connected by a unique synapse to each of the first and second output nodes 510 in the output layer. Accordingly, hundreds of synapses, each having a corresponding weight determined by training the neural network 500, would be used to connect the layer 3 nodes 508 to the output nodes 510, and two mathematical operations collectively using hundreds of input values would be performed in the output layer.

In embodiments, a mathematical operation performed by each of the layer 1 nodes 504, the layer 2 nodes 506, and the layer 3 nodes 508 includes a convolution and a linear rectification (relu). In embodiments, a mathematical operation performed by each of the output nodes 510 includes a convolution and a sigmoid function. However, embodiments are not limited to using these particular functions.

Although FIG. 5 illustrates a fully-connected neural network, embodiments are not limited thereto.

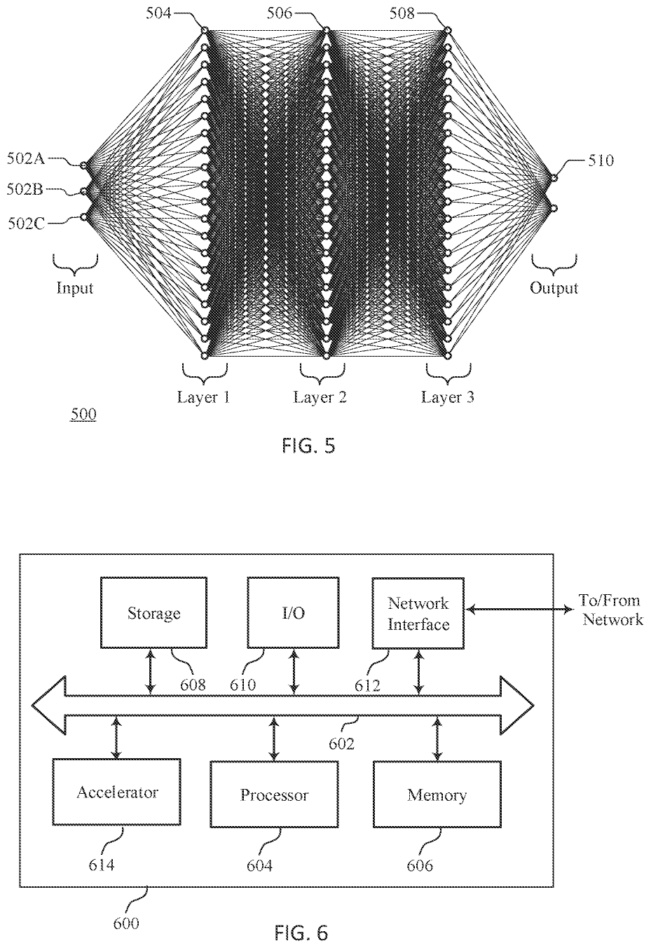

FIG. 6 illustrates an apparatus 600 for performing a design rule check (DRC) process according to an embodiment.

The apparatus 600 includes a processor 604, a memory 606, storage 608, input/output (I/O) interfaces 610, and a network interface 612. In some embodiments, one or more of the components shown in FIG. 6 may be absent from the apparatus 600. In some embodiments, the apparatus 600 further includes an accelerator 614 for accelerating neural network operations.

The memory 606 and the storage 608 may each include non-transient computer-readable media. The memory 606 may include, for example, volatile memory such as Dynamic Random Access Memory (DRAM), nonvolatile memory such as Flash memory, or combinations thereof, but embodiments are not limited thereto. The storage 608 may include, for example, optical disks, hard disk drives, solid-state drives, or combinations thereof, but embodiments are not limited thereto.

Processor 604 may be configured to support the processes for performing design rule checks described herein. In embodiments, the processes for performing design rule checks are performed by the processor 604 executing computer programming instructions stored in the memory 606, the storage 608, or both.

In embodiments of the apparatus 600 including the accelerator 614, steps of the processes described herein that involve a neural network may be performed in whole or part using the accelerator 614. In embodiments, the accelerator 614 may be a Graphics Processing Unit (GPU), a memory device including processing-in-memory, a vector processor, an array processor, or the like, or combinations thereof.

In embodiments, a user of the apparatus 600 may receive information (such as a Final Report) produced using the processes described herein and may provide input and control to the processes described herein through the I/O interface 610 or through a device connected to the apparatus 600 through the network interface 612.

In embodiments, the design Layout Database 102, DRC Deck 104, or DRC Result Dataset 118 of FIG. 1, or combinations thereof, may be stored in the storage 608, in a storage device coupled to the apparatus 600 through the network interface 610, or both.

As described above, SUMMARY, BENEFITS.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A method of performing a design rule check (DRC) performed by a computer, the method comprising:
receiving a DRC result comprising a plurality of DRC errors, the DRC result corresponding to a DRC deck comprising a plurality of rules and a design layout database comprising a plurality of components;
classifying, using a neural network, each of the plurality of DRC errors according to whether that DRC should be ignored; and
producing a final report including a plurality of respective indications of whether the plurality of DRC errors should be ignored,
wherein each DRC error comprises an indication of a rule of the plurality of rules, an indication of a component of the plurality of components, and a count of the number of times the rule was violated by the component.

2. The method of claim 1, wherein classifying the DRC errors comprises:
pre-processing the DRC result to produce a pre-processed DRC result by encoding the indications of the rules into respective rule numerical values and encoding the indications of the components into respective component numerical values; and
providing the pre-processed DRC Result to the neural network.

3. The method of claim 2, wherein encoding the indications of the rules into respective rule numerical values and encoding the indications of the components into respective component numerical values is performed using a label encoder that encodes text values into respective unique values within a numerical range.

4. The method of claim 2, wherein encoding the indications of the rules into respective rule numerical values and encoding the indications of the components into respective component numerical values is performed using a count vectorizer that encodes text values into respective unique Boolean vectors.

5. The method of claim 2, wherein encoding the indications of the rules into respective rule numerical values and encoding the indications of the components into respective component numerical values is performed using a character-based text tokenizer.

6. The method of claim 1, further comprising:
receiving mistake feedback regarding the final report;
updating, using the mistake feedback, a DRC result dataset comprising a plurality of dataset entries; and
re-training the neural network using the updated DRC result dataset,
wherein each of the plurality of dataset entries includes an indication of a rule of the plurality of rules, an indication of a component of the plurality of components, a count of the number of times the rule was violated by the component, and an indication of whether a corresponding DRC error should be ignored.

7. The method of claim 1, wherein each indication of whether a DRC error of the plurality of DRC errors should be ignored comprises a Boolean value.

8. The method of claim 1, wherein each indication of whether a DRC error of the plurality of DRC errors should be ignored comprises a numerical value indicating a confidence level.

9. The method of claim 1, wherein the indication of whether a DRC error of the plurality of DRC errors should be ignored is whether an entry for that DRC error is not present in the final report.

10. A system for performing a design rule check (DRC), the system comprising:
a processor; and
a neural network,
wherein the system is configured to perform steps comprising:
receiving a DRC result comprising a plurality of DRC errors, the DRC result corresponding to a DRC deck comprising a plurality of rules and a design layout database comprising a plurality of components;
classifying, using the neural network, each of the plurality of DRC errors according to whether that DRC error should be ignored; and
producing a final report including a plurality of respective indications of whether the plurality of DRC errors should be ignored,
wherein each DRC error comprises an indication of a rule of the plurality of rules, an indication of a component of the plurality of components, and a count of the number of times the rule was violated by the component.

11. The system of claim 10, wherein classifying the of DRC errors comprises:
pre-processing the DRC result to produce a pre-processed DRC result by encoding the indications of the rules into respective rule numerical values and encoding the indications of the components into respective component numerical values; and
providing the pre-processed DRC Result to the neural network.

12. The system of claim 11, wherein encoding the indications of the rules into respective rule numerical values and encoding the indications of the components into respective component numerical values is performed using a label encoder that encodes text values into respective unique values within a numerical range.

13. The system of claim 11, wherein encoding the indications of the rules into respective rule numerical values and encoding the indications of the components into respective component numerical values is performed using a count vectorizer that encodes text values into respective unique Boolean vectors.

14. The system of claim 11, wherein encoding the indications of the rules into respective rule numerical values and encoding the indications of the components into respective component numerical values is performed using a character-based text tokenizer.

15. The system of claim 10, the steps further comprising:
receiving mistake feedback regarding the final report;
updating, using the mistake feedback, a DRC result dataset comprising a plurality of dataset entries; and
re-training the neural network using the updated DRC result dataset,
wherein each of the plurality of dataset entries includes an indication of a rule of the plurality of rules, an indication of a component of the plurality of components, a count of the number of times the rule was violated by the component, and an indication of whether a corresponding DRC error should be ignored.

16. A computer-readable medium (CRM) that is non-transient and comprising computer programming instructions that, when executed by a processor, perform a method comprising:
receiving a DRC result comprising a plurality of DRC errors, the DRC result corresponding to a DRC deck comprising a plurality of rules and a design layout database comprising a plurality of components;
classifying, using a neural network, each of the plurality of DRC errors according to whether that DRC error should be ignored; and
producing a final report including a plurality of respective indications of whether the plurality of DRC errors should be ignored,
wherein each DRC error comprises an indication of a rule of the plurality of rules, an indication of a component of the plurality of components, and a count of the number of times the rule was violated by the component.

17. The CRM of claim 16, wherein classifying the DRC errors comprises:
pre-processing the DRC result to produce a pre-processed DRC result by encoding the indications of the rules into respective rule numerical values and encoding the indications of the components into respective component numerical values; and
providing the pre-processed DRC Result to the neural network.

18. The CRM of claim 17, wherein encoding the indications of the rules into respective rule numerical values and encoding the indications of the components into respective component numerical values is performed using a label encoder that encodes the indications into respective unique values within a numerical range.

19. The CRM of claim 17, wherein encoding the indications of the rules into respective rule numerical values and encoding the indications of the components into respective component numerical values is performed using a count vectorizer that encodes the indications into respective unique Boolean vectors.

20. The CRM of claim 17, wherein encoding the indications of the rules into respective rule numerical values and encoding the indications of the components into respective component numerical values is performed using a character-based text tokenizer.

21. The CRM of claim 16, the method further comprising:
receiving mistake feedback regarding the final report;
updating, using the mistake feedback, a DRC result dataset comprising a plurality of dataset entries; and
re-training the neural network using the updated DRC result dataset.
